(19) United States
(12) Patent Application Publication
(10) Pub. No.: US 2017/0025416 A1
(43) Pub. Date: Jan. 26, 2017

(54) CAPACITOR STRUCTURES AND METHODS OF FORMING THE SAME, AND SEMICONDUCTOR DEVICES INCLUDING THE SAME

(71) Applicant: Samsung Electronics Co., Ltd., Suwon-si (KR)

(72) Inventors: Jung-Hoon Han, Hwaseong-si (KR); Jong-Min Lee, Hwaseong-si (KR); Dong-Wan Kim, Hwaseong-si (KR); Ju-Ik Lee, Anyang-si (KR)

(21) Appl. No.: 15/067,705

(22) Filed: Mar. 11, 2016

(30) Foreign Application Priority Data
Jul. 22, 2015 (KR) 1020150103464

(51) Int. Cl. H01L 27/108; H01L 29/423; H01L 49/02

(52) U.S. Cl. CPC H01L 27/10814; H01L 28/60; H01L 27/10823; H01L 29/4236

(57) ABSTRACT

A capacitor structure includes a plurality of lower electrodes, a support pattern structure, a dielectric layer, and an upper electrode. The lower electrodes are formed on a substrate. The support pattern structure is formed between the lower electrodes, and includes a lower support pattern and an upper support pattern structure over the lower support pattern. The upper support pattern structure includes a plurality of upper support patterns spaced apart from each other in a direction substantially perpendicular to a top surface of the substrate. The dielectric layer is formed on the lower electrodes and the support pattern structure. The upper electrode is formed on the dielectric layer. A sum of thicknesses of the plurality of upper support patterns in the direction substantially perpendicular to the top surface of the substrate is about 35% to about 85% of a total thickness of the upper support pattern structure.

### CROSS-REFERENCE TO RELATED APPLICATION

This U.S. non-provisional application claims priority under 35 USC §119 to Korean Patent Application No. 10-2015-0103464, filed on Jul. 22, 2015 in the Korean Intellectual Property Office (KIPO), the contents of which are herein incorporated by reference in their entirety.

### BACKGROUND

1. Field

Some example embodiments of the present inventive concepts relate to a capacitor structure and a method of forming the capacitor structure, and a semiconductor device including the capacitor structure. Particularly, some example embodiments relate to a capacitor structure having a support pattern structure, a method of forming the same, and a semiconductor device including the same.

2. Description of the Related Art

As semiconductor devices become more highly integrated, the size of capacitors has been reduced. In consideration of the data input/output characteristics, the capacitor needs a sufficiently high capacitance. In order to increase the effective surface of a lower electrode of the capacitor, one-cylinder-stack (OCS) type capacitors may be used.

The lower electrode of the capacitor may have a high aspect ratio, and, thus, the lower electrode may fall down or be bent resulting in the lower electrode contacting neighboring capacitors.

### SUMMARY

Some example embodiments provide a capacitor structure having an increased effective surface.

Some example embodiments provide a method of forming a capacitor structure having an increased effective surface.

Some example embodiments provide a semiconductor device including a capacitor structure having an increased effective surface.

According to an aspect of the present inventive concepts, there is provided a capacitor structure. The capacitor structure may include a plurality of lower electrodes, a support pattern structure, a dielectric layer, and an upper electrode. The lower electrodes may be formed on a substrate. The support pattern structure may be formed between the lower electrodes, and may include a lower support pattern and an upper support pattern structure over the lower support pattern. The upper support pattern structure may include a plurality of upper support patterns spaced apart from each other in a direction substantially perpendicular to a top surface of the substrate. The dielectric layer may be formed on the lower electrodes and the support pattern structure. The upper electrode may be formed on the dielectric layer. A sum of thicknesses of the plurality of upper support patterns in the direction substantially perpendicular to the top surface of the substrate may be about 35% to about 85% of a total thickness of the upper support pattern structure.

In some example embodiments, a thickness of the lower support pattern may be smaller than the total thickness of the upper support pattern structure.

In some example embodiments, the lower support pattern may include a first support pattern. The upper support pattern structure may include second and third support patterns spaced apart from each other in the direction substantially perpendicular to the top surface of the substrate, and a distance between the second and third support patterns in the direction substantially perpendicular to the top surface of the substrate may be about 15% to about 65% of the total thickness of the upper support pattern structure.

In some example embodiments, an upper surface of the upper support pattern structure may be lower than top surfaces of the lower electrodes.

In some example embodiments, the lower support pattern and the upper support pattern structure may include silicon nitride or silicon carbonitride.

In some example embodiments, each of the lower support pattern and the upper support pattern structure may extend in a direction substantially parallel to the top surface of the substrate between sidewalls of the lower electrodes.

In some example embodiments, each of the lower support pattern and the upper support pattern structure may partially connect the sidewalls of the lower electrodes to each other.

In some example embodiments, the upper support pattern structure may vertically overlap the lower support pattern.

In some example embodiments, the lower electrode may have a cylindrical shape.

According to another aspect of the present inventive concepts, there is provided a semiconductor device. The semiconductor device may include a transistor on a substrate, and a capacitor structure electrically connected to the transistor. The capacitor structure may include a plurality of lower electrodes, a support pattern structure, a dielectric layer, and an upper electrode. The lower electrodes may be formed on a substrate. The support pattern structure may be formed between the lower electrodes, and may include a lower support pattern and an upper support pattern structure over the lower support pattern. The upper support pattern structure may include a plurality of upper support patterns spaced apart from each other in a direction substantially perpendicular to a top surface of the substrate. The dielectric layer may be formed on the lower electrodes and the support pattern structure. The upper electrode may be formed on the dielectric layer. A sum of thicknesses of the plurality of upper support patterns in the direction substantially perpendicular to the top surface of the substrate may be about 35% to about 85% of a total thickness of the upper support pattern structure.

In some example embodiments, the lower support pattern may include a first support pattern. The upper support pattern structure may include second and third support patterns spaced apart from each other in the direction substantially perpendicular to the top surface of the substrate, and a distance between the second and third support patterns in the direction substantially perpendicular to the top surface of the substrate may be about 15% to about 65% of the total thickness of the upper support pattern structure.

In some example embodiments, an upper surface of the upper support pattern structure may be lower than top surfaces of the lower electrodes.

In some example embodiments, each of the lower support pattern and the upper support pattern structure may extend in a direction substantially parallel to the top surface of the substrate between sidewalls of the lower electrodes. The upper support pattern structure may vertically overlap the lower support pattern.

In some example embodiments, the transistor may include a gate structure buried in the substrate.

In some example embodiments, semiconductor device may further include a contact plug electrically connected to the transistor. The contact plug may contact the capacitor structure.

According to another aspect of the present inventive concepts, there is provided a method of forming a capacitor structure. In the method, a first mold layer, a first support layer, a second mold layer, a second support layer, a third mold layer and a third support layer may be sequentially formed. A first opening may be formed through the first to third support layers and the first to third mold layers. A lower electrode may be formed on a bottom and a sidewall of the first opening. The first to third mold layers and portions of the first to third support layers may be removed to form a support pattern structure including first to third support patterns. A dielectric layer may be formed on the lower electrode and the support pattern structure. An upper electrode may be formed on the dielectric layer. The first and second mold layers may include silicon oxide, and the third mold layer may include silicon oxynitride.

In some example embodiments, when the support pattern structure is formed, the third support layer may be partially removed until an upper surface of the third mold layer may be exposed to form the third support pattern. The third mold layer may be removed. The second support layer may be partially removed until an upper surface of the second mold layer may be exposed to formed the second support pattern. The second mold layer may be removed. The first support layer may be partially removed until an upper surface of the first mold layer may be exposed to form the first support pattern. The first mold layer may be removed.

In some example embodiments, the first, second and third support layers may be partially removed by an etch back process.

In some example embodiments, the first, second and third mold layers may be removed by a wet etching process.

In some example embodiments, a bottom of the third support layer may be spaced apart from an upper surface of the second support layer by a first distance, an upper surface of the third support may be spaced apart from a bottom of the second support layer by a second distance. The first distance may be about 15% to about 65% of the second distance.

In accordance with another aspect of the present inventive concepts, there is provided a capacitor structure. The capacitor structure includes a plurality of lower electrodes on a substrate and a lower support pattern between the lower electrodes and spaced apart from the substrate in a first direction. The first direction is substantially perpendicular to a direction of extension of an upper surface of the substrate. The capacitor structure further includes an upper support pattern structure including a plurality of upper support patterns between the plurality of lower electrodes and spaced apart from the lower support pattern in the first direction. The plurality of upper support patterns are spaced apart from each other in the first direction. The capacitor structure further includes a dielectric layer on the lower electrodes, the lower support pattern and the plurality of upper support patterns and an upper electrode on the dielectric layer. A sum of distances between the plurality of upper support patterns in the first direction is about 15% to about 65% of a total thickness of the upper support pattern structure.

In some embodiments, the lower support pattern includes a first support pattern and the plurality of upper support patterns include second and third support patterns spaced apart from each other in the first direction. A distance between the second and third support patterns in the first direction is about 15% to about 65% of the total thickness of the upper support pattern structure, and a sum of thicknesses of the plurality of upper support patterns in the first direction is about 35% to about 85% of a total thickness of the upper support pattern structure.

In some embodiments, an upper surface of the upper support pattern structure is lower than top surfaces of the lower electrodes.

In some embodiments, each of the lower support pattern and the upper support pattern structure extends in a direction substantially parallel to the top surface of the substrate between sidewalls of the lower electrodes, and each of the lower support pattern and the upper support pattern structure partially connects the sidewalls of the lower electrodes to each other.

In some embodiments, the upper support pattern structure vertically overlaps the lower support pattern.

The capacitor structure in accordance with some example embodiments of the present inventive concepts may include the support pattern structure supporting the lower electrodes, and, thus, may prevent lower electrodes from falling down or leaning. The support pattern structure may include a plurality of support patterns spaced apart from each other in a vertical direction, and, thus, the effective surface of the lower electrodes may be enlarged. Accordingly, the lower electrodes may be sufficiently supported by the support pattern structure, and, simultaneously, the capacitance of the capacitor structure may be enhanced.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIGS. 1 and 2 are a plan view and a cross-sectional view, respectively, illustrating a semiconductor device in accordance with some example embodiments;

FIGS. 3, 5, 8, 10 and 18 are plan views illustrating stages of a method of manufacturing a semiconductor device in accordance with some example embodiments; and

FIGS. 4, 6-7, 9, 11-17, 19 and 20 are cross-sectional views illustrating the stages of the method of manufacturing the semiconductor device in accordance with some example embodiments.

### DESCRIPTION OF EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein.

It will be understood that when an element or layer is referred to as being “on,” “connected to” or “coupled to” another element or layer, it can be directly on, connected or coupled to the other element or layer or intervening elements or layers may be present. In contrast, when an element or layer is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

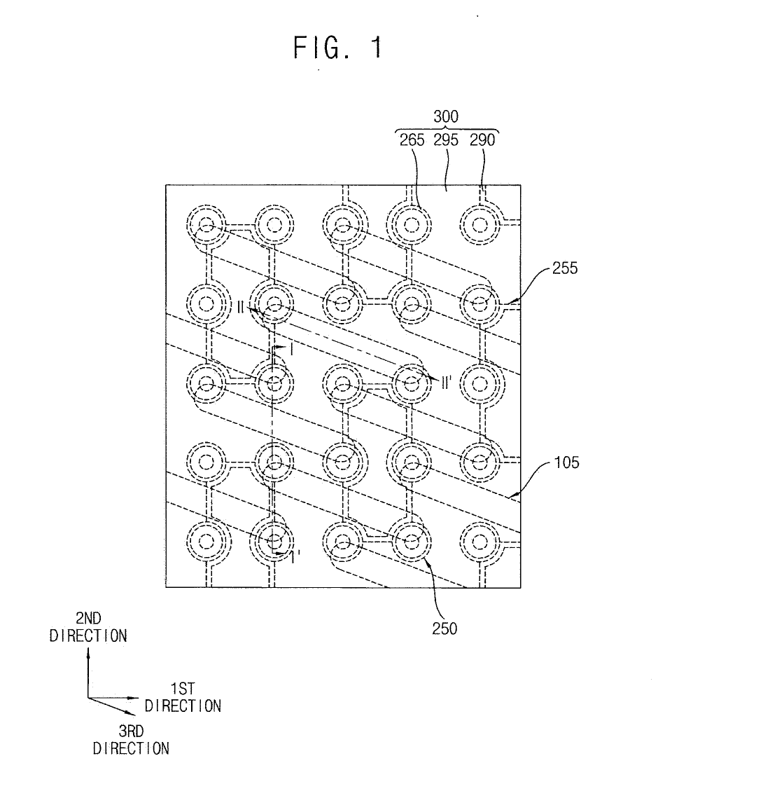

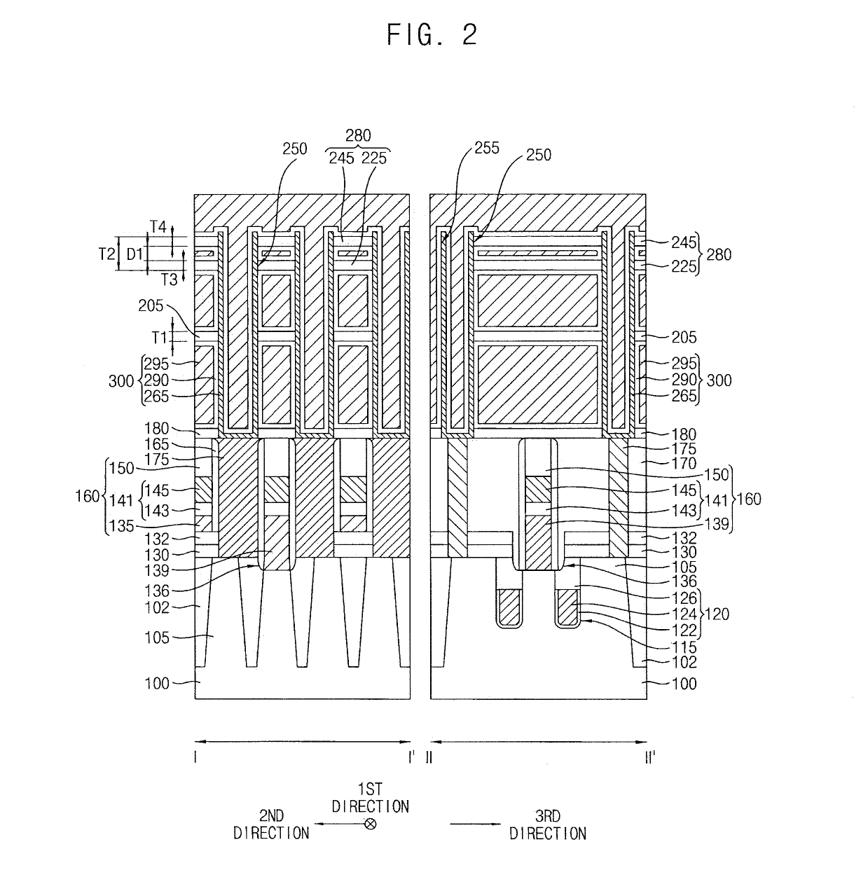

FIGS. 1 and 2 are a plan view and a cross-sectional view, respectively, illustrating a semiconductor device in accordance with example embodiments. Particularly, FIG. 2 includes cross-sections taken along lines I-I′ and II-II′, respectively, in FIG. 1. The line I-I′ may extend in a second direction substantially parallel to a top surface of a substrate 100. The line II-II′ may extend in a third direction substantially parallel to the top surface of the substrate 100 and substantially parallel to a direction in which an active region 105 may extend.

Referring to FIGS. 1 and 2, the semiconductor device may include a transistor on the substrate 100, and a capacitor structure electrically connected to the transistor. The capacitor structure may be formed on the transistor. The capacitor structure may include a capacitor 300 and a support pattern structure for supporting the capacitor 300. The semiconductor device may further include a contact plug 175, a bit line structure 160, an insulation layer 132, an insulating interlayer 170, and first and second etch stop layers 130 and 180.

The substrate 100 may include, for example, a semiconductor material, for example, silicon, germanium, silicon-germanium, or the like, or III-V semiconductor compounds, for example, GaP, GaAs, GaSb, or the like. In some example embodiments, the substrate 100 may be a silicon-on-insulator (SOI) substrate or a germanium-on-insulator (GOI) substrate. The substrate 100 may be divided into an active region and a field region by an isolation layer 102.

In some example embodiments, the active region may include a plurality of active patterns 105. Each of the active patterns 105 may extend in the third direction. The third direction may be substantially parallel to the top surface of the substrate 100, but may be neither perpendicular nor parallel to the second direction. That is, the third direction may have an acute angle with respect to the second direction. The third direction may be slanted relative to the first and second directions.

A trench 115 may be formed in the substrate 100. In some example embodiments, a bottom of the trench 115 may be higher than a bottom of the isolation layer 102.

The transistor may include a gate structure 120 and an impurity region at an upper portion of the substrate 100 adjacent the gate structure 120 (not shown). The impurity region may be a source/drain region of the transistor.

The gate structure 120 may fill the trench 115. A top surface of the gate structure 120 may be substantially coplanar, or level, with a top surface of the isolation layer 102. The gate structure 120 may include a gate insulation pattern 122, a gate electrode 124 and a capping pattern 126.

The gate insulation pattern 122 may be formed on a lower inner wall of the trench 115, and may include, for example, silicon oxide or a metal oxide.

The gate electrode 124 may be formed on the gate insulation pattern 122, and may fill a lower portion of the trench 115. That is, the gate electrode 124 may fill the portion of the trench 115 covered by the gate insulation pattern 122. The gate electrode 124 may include, for example, a metal, for example, tungsten, titanium, aluminum, or the like, a metal nitride, for example, tungsten nitride, titanium nitride, aluminum nitride, or the like, or doped polysilicon.

The capping pattern 126 may be formed on the gate insulation pattern 122 and the gate electrode 124, and may fill an upper portion of the trench 115. The capping pattern 126 may include, for example, silicon nitride or silicon oxynitride. The top surface of the capping pattern 126 may be substantially coplanar, or level, with the top of the isolation layer 102.

The first etch stop layer 130 and the insulation layer 132 may be sequentially stacked on the substrate 100, and may partially cover a top surface of the gate structure 120.

A plurality of holes 136 may be formed through the first etch stop layer 130 and the insulating interlayer 132. A portion of an upper surface of the gate structure 120 and a portion of an upper surface of the active pattern 105 between neighboring ones of the gate structures 120 may be exposed by the holes 136. The bit line structure 160 may contact the exposed upper surface of the active pattern 105 through the holes 136. Sidewalls of the bit line structures 160 in the holes 136 may be spaced apart from sidewalls of the holes 136. In some example embodiments, a bottom of the hole 136 may be lower than the top surface of the gate structure 120. That is, a portion of the capping pattern 126 and the active pattern 105 between neighboring ones of the gate structures 120 may be etched in forming the plurality of holes 136.

The first etch stop layer 130 may include, for example, a nitride, for example, silicon nitride, silicon oxynitride, or the like.

The insulation layer 132 may be formed on the first etch stop layer 130. The insulation layer 132 may include, for example, silicon oxide, for example, plasma enhanced oxide (PEOX), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), boro phospho silicate glass (BPSG), or the like.

The insulating interlayer 170 may be formed on the insulation layer 132 and may fill the plurality of hole 136. The insulating interlayer 170 may include, for example, a material substantially the same as that of the insulation layer 132.

The bit line structure 160 may penetrate through the insulating interlayer 170, and may contact the upper surface of the active pattern 105 exposed by the hole 136. The insulating interlayer 170 may remain in holes 136 between the bit line structure 160 and sidewalls of the hole 136.

In some example embodiments, the bit line structure 160 may include a first conductive pattern 135, a second conductive pattern 139, a third conductive pattern 141 and a second hard mask 150. The third conductive pattern 141 may include a barrier pattern 143 and a metal pattern 145 sequentially stacked on the first and second conductive patterns 135 and 139.

The first and second conductive patterns 135 and 139 may include, for example, doped polysilicon. The barrier pattern 143 may include, for example, a metal nitride, and the metal pattern 145 may include a metal, for example, tungsten, aluminum, copper, or the like. The second hard mask 150 may include, for example, a nitride, for example, silicon nitride.

The bit line structure 160 may include the second conductive pattern 139, the third conductive pattern 141 and the second hard mask 150 sequentially stacked on a portion of the substrate 100 on which the hole 136 is formed. The second conductive pattern 139 may contact the upper surface of the active pattern 105 exposed by the hole 136. That is, the second conductive pattern 139 may serve as a bit line contact.

The bit line structure 160 may include the first conductive pattern 135, the third conductive pattern 141 and the second hard mask 150 sequentially stacked on a portion of the substrate 100 on which the hole 136 is not formed. A bottom of the first conductive pattern 135 may contact a top surface of the insulation layer 132. The bit line structure 160 including the first conductive pattern 135, the third conductive pattern 141 and the second hard mask 150 may extend in a first direction. The first direction may be substantially parallel to the top surface of the substrate 100 and substantially perpendicular to the second direction. A plurality of bit line structures 160 may be formed in the second direction.

In some example embodiments, the bit line structure 160 may have a width smaller than a width of the hole 136, and, thus, a sidewall of the bit line structure 160 may be spaced apart from a sidewall of the hole 136.

A spacer 165 may be further formed on a sidewall of the bit line structure 160. The spacer 165 may include, for example, a nitride, for example, silicon nitride. The spacer 165 may contact the capping pattern 126 and the active pattern 105 exposed by the hole 136. The spacer 165 may extend in the first direction, and a plurality of spacers 165 may be formed in the second direction. The bit line structure 160 may not contact the contact plug 175 due to the spacer 165. That is, the spacer 165 may be formed between the bit line structure 160 and the contact plug 175.

The contact plug 175 may penetrate through the insulating interlayer 170, the insulation layer 132 and the first etch stop layer 130, and may contact an upper surface of the impurity region at the upper portion of the substrate 100. The contact plug 175 may also contact an upper surface of the isolation layer 102. The contact plug 175 may be a capacitor contact.

The second etch stop layer 180 may be formed on the insulating interlayer 170, and the capacitor 300 may be formed on a portion of the insulating interlayer 170 not covered by the second etch stop layer 180. That is, the second etch stop layer 180 may expose portions of the insulating interlayer 170 and the contact plug 175. The second etch stop layer 180 may include a material substantially the same as that of the first etch stop layer 130.

The capacitor 300 may include a lower electrode 265, a dielectric layer 290 and an upper electrode 295 sequentially stacked. The capacitor structure may include the capacitor 300, and the support pattern structure connecting the lower electrodes 265 with each other.

In some example embodiments, the lower electrode 265 may have a cylindrical shape on an inner wall of a first opening 250. However, the inventive concepts may not be limited thereto, and, for example, a pillar-type capacitor may be formed. The lower electrode 265 may contact an upper surface of the contact plug 175, and may be electrically connected thereto. The lower electrodes 265 may contact an upper surface of insulating interlayer 170 exposed by etch stop layer 180.

The support pattern structure may include a lower support pattern and an upper support pattern structure 280. The lower support pattern may include a first support pattern 205, and the upper support pattern structure 280 may include a second support pattern 225 and a third support pattern 245. The first, second and third support patterns 205, 225 and 245 may include, for example, silicon nitride or silicon carbonitride.

In a plan view, the support pattern structure may connect the lower electrodes 265, and may not be formed on a portion of the substrate 100 on which a second opening 255 is formed. In FIG. 1, the second opening 255 has a substantially rectangular shape as a whole that may be formed by six neighboring lower electrodes 265; however, the inventive concepts may not be limited thereto, and the second opening 255 may have various other shapes.

The lower support pattern may have a first thickness T1, and the upper support pattern structure 280 may have a second thickness T2. In some example embodiments, the first thickness T1 may be smaller than the second thickness T2.

In the upper support pattern structure 280, the second support pattern 225 may have a third thickness T3, and the third support pattern 245 may have a fourth thickness T4. The second support pattern 225 and the third support pattern 245 may be spaced apart from each other by a first distance D1. A total thickness of the upper support pattern structure 280, which may be defined, hereinafter, as a sum of the third and fourth thicknesses T3 and T4 and the first distance D1, may be substantially equal to the second thickness T2. That is, the second thickness T2 is the combination of the third thickness T3, the fourth thickness T4 and the first distance D1.

In some example embodiments, a sum of the thicknesses of the second support pattern 225 and the third support pattern 245, that is, T3+T4, may be about 35% to about 85% of the total thickness of the upper support pattern structure 280, that is, the second thickness T2. Thus, the first distance D1 between the second support pattern 225 and the third support pattern 245 may be about 15% to about 65% of the second thickness T2 of the upper support pattern structure 280. If the first distance D1 is less than about 15% of the second thickness T2 of the upper support pattern structure 280, the dielectric layer 290 may not be formed between the second support pattern 225 and the third support pattern 245. If the first distance D1 is more than about 65% of the second thickness T2 of the upper support pattern structure 280, the lower electrode 265 may not be sufficiently supported. Thus, the first distance D1 may be between 15% and 65% of the second thickness T2.

When the upper support pattern structure 280 is formed, the second and third support patterns 225 and 245 may be formed to be spaced apart from each other by the first distance D1, and, thus, a surface of the lower electrode 265 contacting the upper electrode 295 may be increased by the first distance D1. When compared to an embodiment in which an upper support pattern structure 280 has a single support pattern, the upper support pattern structure 280 may have the second thickness T2 substantially the same as the embodiment having a single support pattern. However, the upper support pattern structure 280 may include a plurality of support patterns 225 and 245 spaced apart from each other by the first distance D1, resulting in the surface of the lower electrode 265 contacting the dielectric layer 290 being increased thereby enhancing the capacitance of the capacitor 300.

In some example embodiments, the upper support pattern structure 280 may include more support patterns in addition to the second and third support patterns 225 and 245. In such an embodiment, a sum of thicknesses of support patterns of the upper support pattern structure 280 may be about 35% to about 85% of the total thickness of the upper support pattern structure 280. In such an embodiment, a sum of distances between support patterns may be between 15% and 65% of the total thickness of upper support pattern structure 280.

The dielectric layer 290 may cover an upper surface and a sidewall of the lower electrode 265, an upper surface of the second etch stop layer 180, and upper and lower surfaces of the first, second and third support patterns 205, 225 and 245. The dielectric layer 290 may include, for example, a metal oxide, for example, hafnium oxide, zirconium oxide, or the like.

The upper electrode 295 may include, for example, a metal, for example, titanium, tungsten, tantalum, ruthenium, or the like, or a metal nitride, for example, titanium nitride, tungsten nitride, tantalum nitride, or the like.

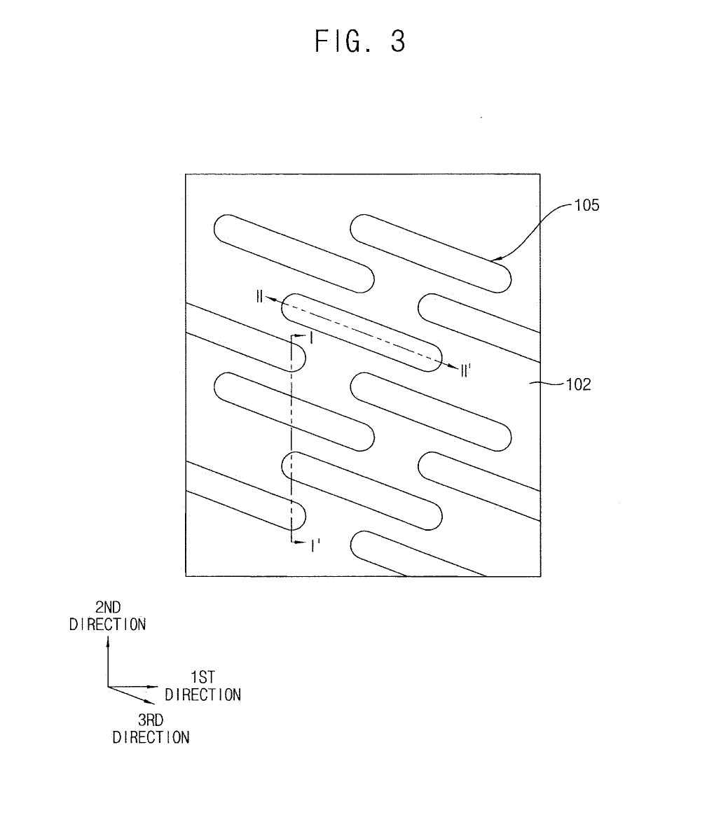

A method of manufacturing the semiconductor device in FIG. 1 will be illustrated in connection with FIGS. 3-20.

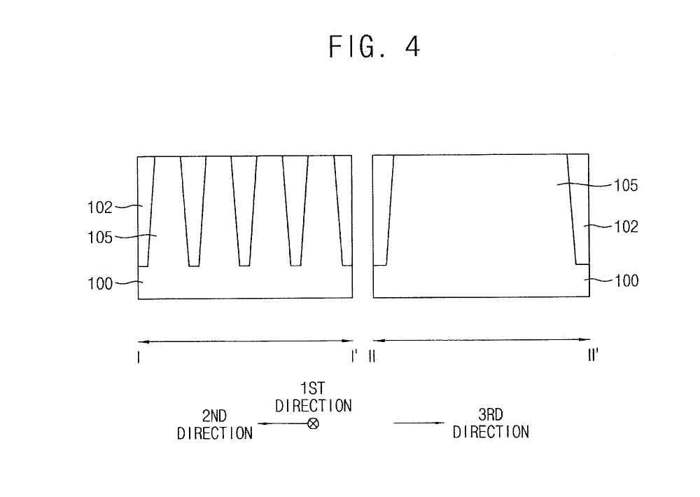

FIGS. 3, 5, 8, 10 and 18 are plan views illustrating stages of a method of manufacturing a semiconductor device in accordance with example embodiments, and FIGS. 4, 6-7, 9, 11-17, 19 and 20 are cross-sectional views illustrating the stages of the method of manufacturing the semiconductor device in accordance with some example embodiments.

Each of the cross-sectional views may include cross-sections taken along lines I-I′ and respectively, in corresponding plan views. The line I-I′ may extend in a second direction substantially parallel to a top surface of the substrate 100. The line II-II′ may extend in a third direction which is substantially parallel to the top surface of the substrate 100 and substantially parallel to a direction in which an active region 105 may extend.

Referring to FIGS. 3 and 4, an isolation layer 102 may be formed on a substrate 100.

The substrate 100 may include, for example, a semiconductor material, for example, silicon, germanium, silicon-germanium, or the like, or III-V semiconductor compounds, for example, GaP, GaAs, GaSb, or the like. In some example embodiments, the substrate 100 may be an SOI substrate or a GOI substrate. The substrate 100 may be divided into an active region and a field region by an isolation layer 102.

The isolation layer 102 may be formed, for example, of an oxide, for example, silicon oxide, and may be formed on the substrate 100 by, for example, a shallow trench isolation (STI) process. The isolation layer 102 may extend in a substantially vertical direction of extension relative to a substantially horizontal direction of extension of the substrate 100.

A portion of the substrate 100 on which the isolation layer 102 is formed may be defined as a field region, and a portion of the substrate 100 on which the isolation layer 102 is not formed may be defined as an active region. In some example embodiments, the active region may include a plurality of active patterns 105, and each of the active patterns 105 may extend in the third direction. The third direction may be substantially parallel to the top surface of the substrate 100 and may not be parallel to the second direction and may not be perpendicular to the second direction. That is, the third direction may be slanted relative to the first and second direction. An upper surface of the active pattern 105 may be substantially coplanar, or level, with the isolation layer 102.

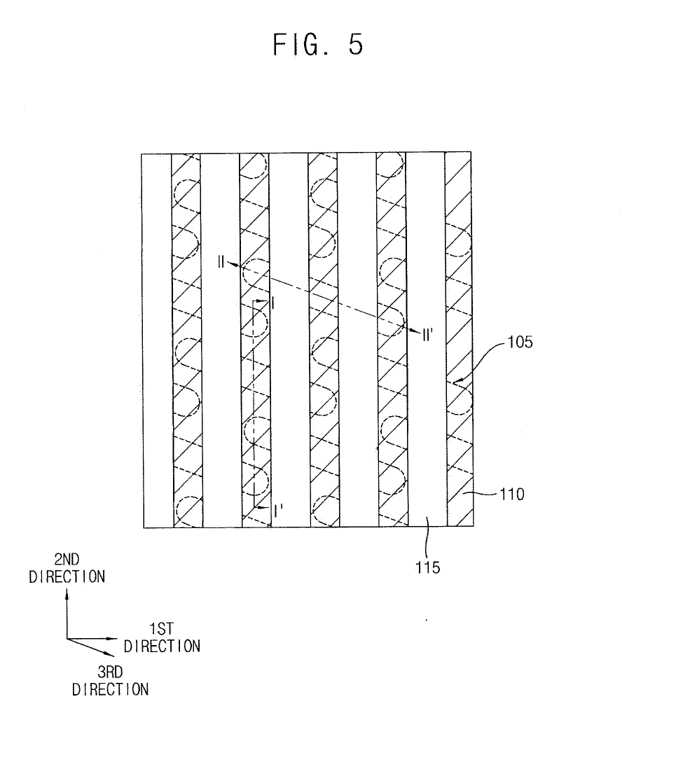

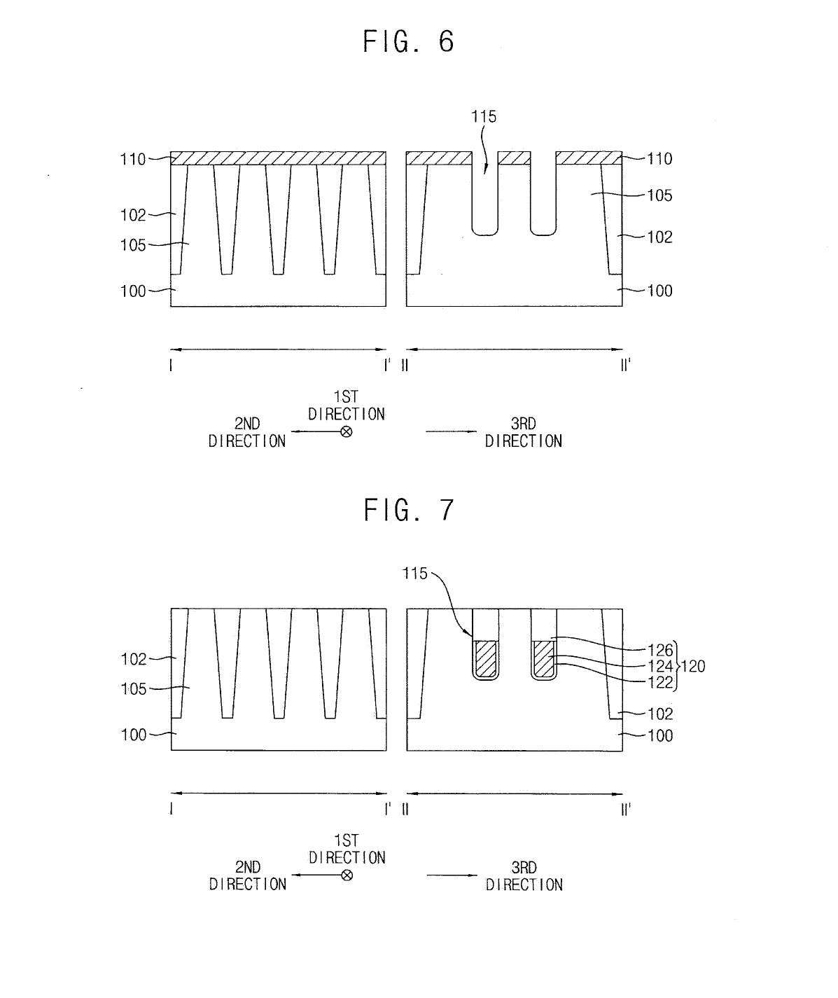

Referring to FIGS. 5 and 6, a first hard mask 110 may be formed on the isolation layer 102 and the active patterns 105 to extend in the second direction and a plurality of first hard masks 110 may be formed spaced apart from each other in a first direction.

The first hard mask 110 may be formed by sequentially forming a mask layer and a photoresist pattern (not shown) on the substrate 100 and the isolation layer 102, and etching the mask layer using the photoresist pattern as an etching mask. For example, the mask layer may be formed by a chemical vapor deposition (CVD) process, a spin-coating process, or the like. The first hard mask 110 may extend in the second direction, and a plurality of first hard masks 110 may be formed along a first direction. The first direction may be substantially parallel to the top surface of the substrate 100 and substantially perpendicular to the second direction.

An etching process may be performed using the first hard mask 110 as an etching mask to form a trench 115 in the substrate 100. For example, the etching process may include a dry etching process or a reactive ion etching (RIE) process. The trench 115 may extend in a substantially vertical direction of extension relative to a substantially horizontal direction of extension of the substrate 100.

The trench 115 may extend in the second direction, and a plurality of trenches 115 may be formed spaced apart from each other along the first direction. In some example embodiments, a bottom of the trench 115 may be higher than a bottom of the isolation layer 102. As a result, neighboring elements may be effectively insulated from each other by the isolation layer 102.

Referring to FIG. 7, a gate structure 120 filling the trench 115 may be formed to extend in the second direction.

The gate structure 120 may include a gate insulation pattern 122 and a gate electrode 124, which may fill a lower portion of the trench 115, and a capping pattern 126 on the gate insulating pattern 122 and the gate electrode 124 that may fill an upper portion of the trench 115.

In some example embodiments, a portion of the substrate 100 exposed by the trench 115 may be thermally oxidized to form a gate insulation layer. Alternatively, the gate insulation layer may be formed of, for example, silicon oxide or a metal oxide, by, for example, a CVD process.

A gate electrode layer may be formed on the gate insulation layer to fill a remaining portion of the trench 115. The gate electrode layer may be formed of, for example, a metal, for example, tungsten, titanium, aluminum, or the like, and/or a metal nitride, for example, tungsten nitride, titanium nitride, aluminum nitride, or the like, by, for example, a CVD process, an atomic layer deposition (ALD) process, a physical vapor deposition (PVD) process, or the like. In some example embodiments, the gate electrode layer may be formed of doped polysilicon.

The gate electrode layer and the gate insulation layer may be planarized until a top surface of the substrate 100 may be exposed by, for example, a chemical mechanical polishing (CMP) process, and an etch back process may be further performed to remove upper portions of the gate electrode layer and the gate insulation layer to form a gate insulation pattern 122 and a gate electrode 124 sequentially stacked in the lower portion of the trench 115.

A capping layer may be formed on the gate electrode 124 and the gate insulation pattern 122 to sufficiently fill a remaining portion of the trench 115, and may be planarized until the top surface of the substrate 100 may be exposed to form a capping pattern 126. An upper surface of the capping pattern 126 may be substantially coplanar, or level, with the upper surface of the isolation layer 102 and the active patterns 105.

The capping layer may be formed of, for example, a nitride, for example, silicon nitride, silicon oxynitride, or the like, by, for example, a CVD process, an ALD process, or the like.

The gate insulation pattern 122, the gate electrode 124 and the capping pattern 126 may form the gate structure 120.

An ion implantation process may be performed to form an impurity region (not shown) at an upper portion of the substrate 100 adjacent the gate structure 120, that is, at an upper surface of the active patterns 105.

The gate structure 120 and the impurity region may form a transistor. The impurity region may be a source/drain region of the transistor.

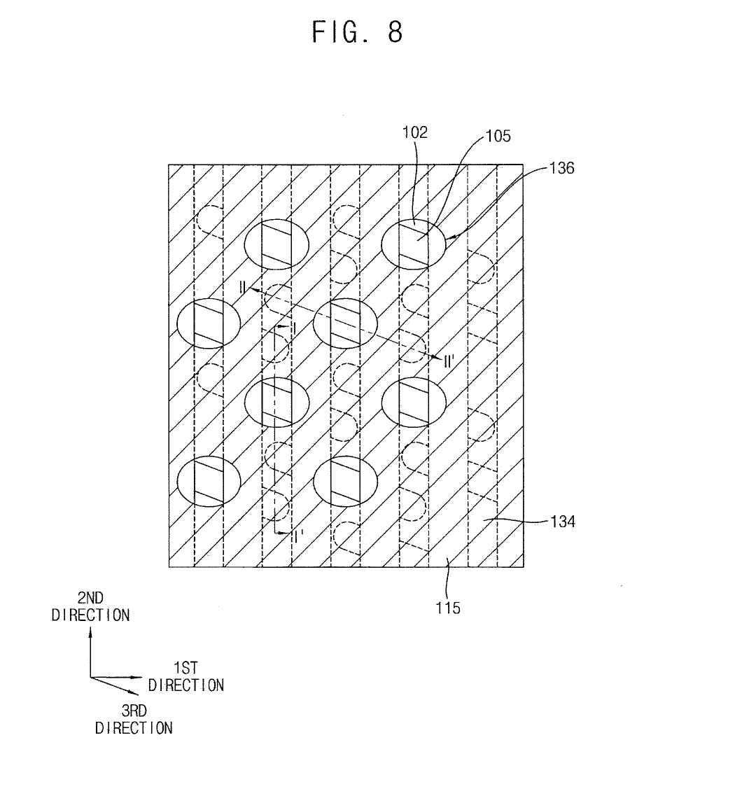

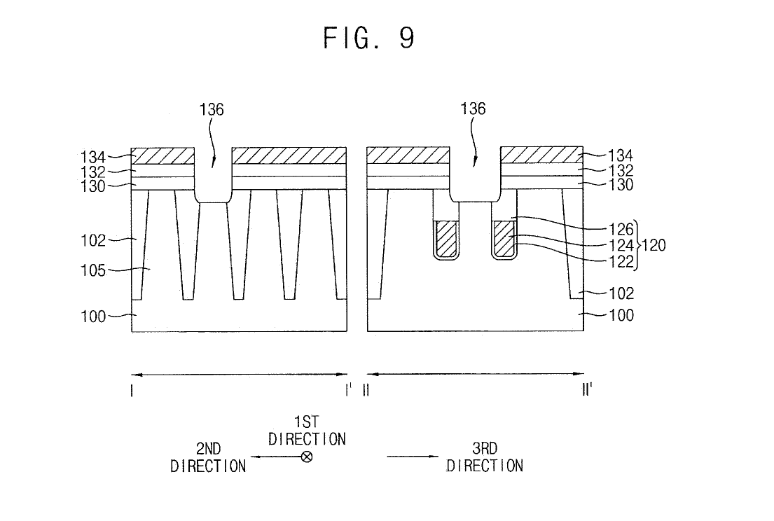

Referring to FIGS. 8 and 9, a first etch stop layer 130, an insulation layer 132 and a first conductive layer 134 may be sequentially formed on the substrate 100 and the gate structure 120.

The first etch stop layer 130 may be formed of, for example, a nitride, for example, silicon nitride, silicon oxynitride, or the like, by, for example, a CVD process, an ALD process, or the like.

The insulation layer 132 may be formed of, for example, an oxide, for example, silicon oxide, by, for example, a CVD process, an ALD process, or the like.

The first conductive layer 134 may be formed of, for example, doped polysilicon.

The first conductive layer 134, the insulation layer 132 and the first etch stop layer 130 may be partially etched to form holes 136. Each of the holes 136 may expose a portion of the active pattern 105 between the gate structures 120. In some example embodiments, the holes 136 may expose a portion of the capping pattern 126 and a portion of the isolation layer 102. In some example embodiments, each of the holes 136 may expose a central upper surface of each of the active patterns 105. During the formation of the holes 136, upper portions of the capping pattern 126 and the isolation layer 102 may be also removed. The holes 136 may be formed between adjacent gate structures. The holes 136 extend in a substantially vertical direction of extension relative to a substantially horizontal direction of extension of the substrate 100.

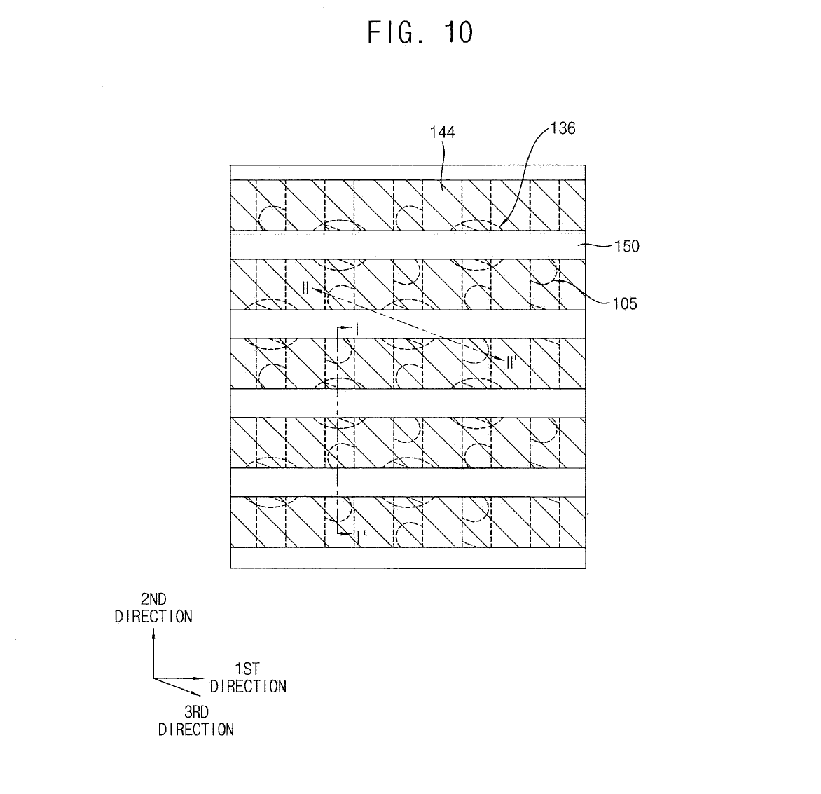

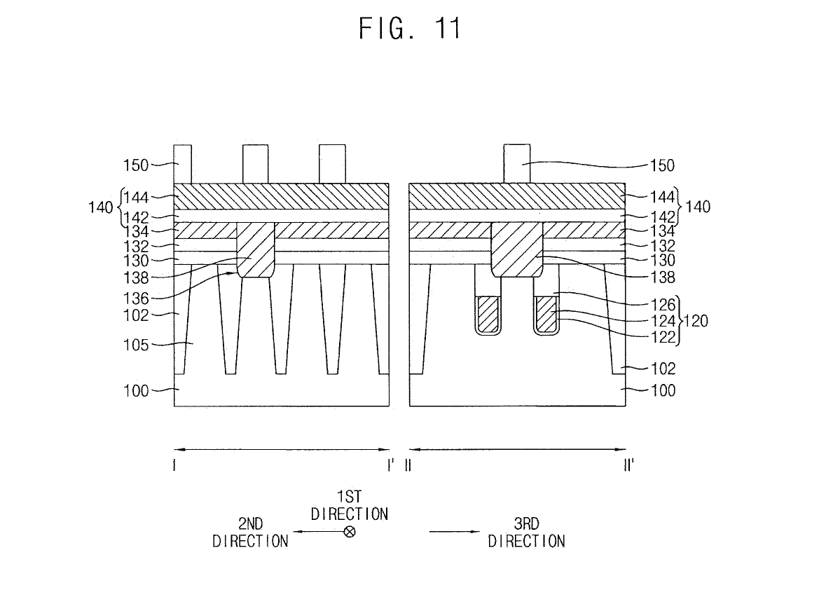

Referring to FIGS. 10 and 11, a second conductive layer 138 may be formed to fill the holes 136. An upper surface of the second conductive layer 138 may be substantially coplanar, or level, with an upper surface of the first conductive layer 134.

The second conductive layer 138 may be formed of a material substantially the same as that of the first conductive layer 134, for example, doped polysilicon.

A third conductive structure 140 including a barrier layer 142 and a metal layer 144 may be formed on the first and second conductive layers 134 and 138. A second hard mask 150 may be formed on the third conductive structure 140 extending in the first direction and a plurality of second hard masks 150 may be formed spaced apart from each other along the second direction.

The barrier layer 142 may be formed of, for example, a metal nitride, and the metal layer 144 may be formed of, for example, a metal, for example, tungsten, aluminum, copper, or the like. The barrier layer 142 may prevent the diffusion of metal in the metal layer 144 into neighboring elements, and may enhance the adhesion between the metal layer 144 and the first and second conductive layers 134 and 138.

The second hard mask 150 may be formed by a process substantially the same as the process for forming the first hard mask 110, and may include a material substantially the same as that of the first hard mask 110. The second hard mask 150 may extend in the first direction, and a plurality of second hard masks 150 may be formed spaced apart from each other in the second direction.

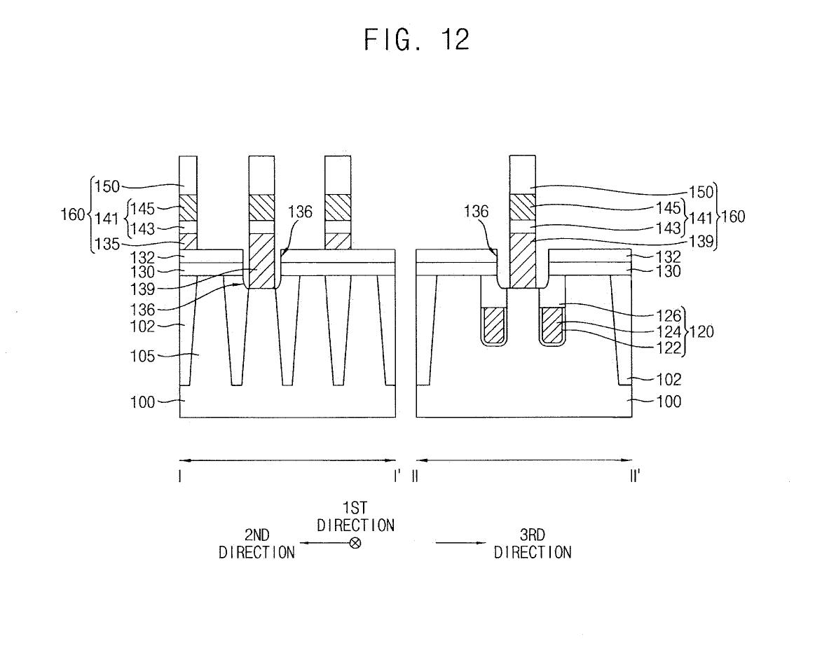

Referring to FIG. 12, an etching process may be performed using the second hard mask 150 as an etching mask to sequentially etch the third conductive structure 140, the second conductive layer 138 and the first conductive layer 134. As a result, a bit line structure 160 including a first conductive pattern 135, a second conductive pattern 139, a third conductive pattern 141 and the second hard mask 150 sequentially stacked may be formed. An upper surface and a sidewall of the insulation layer 132, a sidewall of the first etch stop layer 130, and a top surface of the substrate 100 may be partially exposed. A portion of the capping pattern 126 and the isolation layer 102 in hole 136 may be exposed. Each of the first conductive pattern 135 and the third conductive pattern 141 may extend in the first direction like the second hard mask 150, and a plurality of first conductive patterns 135 and a plurality of third conductive patterns 141 may be formed in the second direction.

In some example embodiments, the bit line structure 160 may have a width smaller than that of the hole 136. As a result, a sidewall of the bit line structure 160 may be spaced apart from a sidewall of the hole 136.

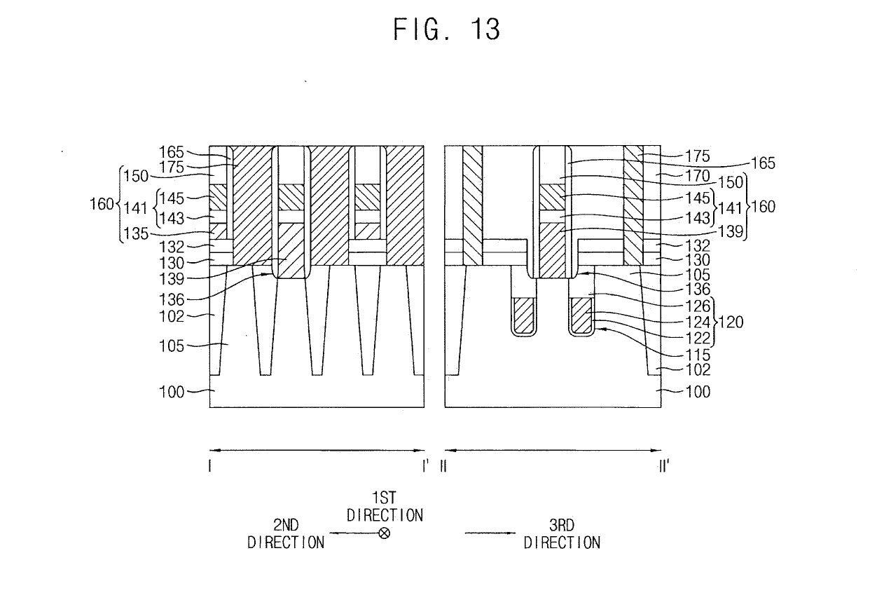

Referring to FIG. 13, a spacer 165 may be forming on a sidewall of the bit line structure 160. A sidewall of the spacer 165 may be spaced apart from the sidewall of the hole 136.

The spacer 165 may be formed by forming a spacer layer on the bit line structure 160, the insulation layer 132, the first etch stop layer 130 and the substrate 100, and anisotropically etching the spacer layer. The spacer layer may be formed of, for example, a nitride, for example, silicon nitride.

An insulating interlayer 170 may be formed on the insulation layer 132 and the substrate 100 to cover the bit line structure 160 and the spacer 165. The insulating interlayer 170 may fill the holes 136. The insulating interlayer 170 may be formed, for example, of silicon oxide, for example, PEOX, BTEOS, PTEOS, BPTEOS, BSG, PSG, BPSG, or the like, by, for example, a CVD process, an ALD process, or the like.

The insulating interlayer 170, the insulation layer 132 and the first etch stop layer 130 may be partially etched to form contact holes (not shown) each of which may expose an upper surface of the active pattern 105 and may also expose an upper surface of the isolation layer 102. The contact hole may extend in a substantially vertical direction of extension relative to a substantially horizontal direction of extension of the substrate 100.

Contact plugs 175 filling the contact holes, respectively, may be formed to be electrically connected to the active pattern 105. Particularly, a conductive layer may be formed to fill the contact holes, and an upper portion of the conductive layer may be planarized until a top surface of the second hard mask 150 may be exposed to form the contact plugs 175. An upper surface of the contact plug 175 may be substantially coplanar, or level, with upper surfaces of the insulating interlayer 170 and the second hard mask 150. The conductive layer may be formed of, for example, a metal, for example, tungsten, copper, aluminum, or the like, and/or a metal nitride thereof, by, for example, a CVD process, an ALD process, a PVD process, or the like. In some example embodiments, the planarization process may be performed by, for example, a CMP process and/or an etch back process.

The contact plug 175 may contact a capacitor 300 (refer to FIG. 1) subsequently formed, and, as a result, may be a capacitor contact.

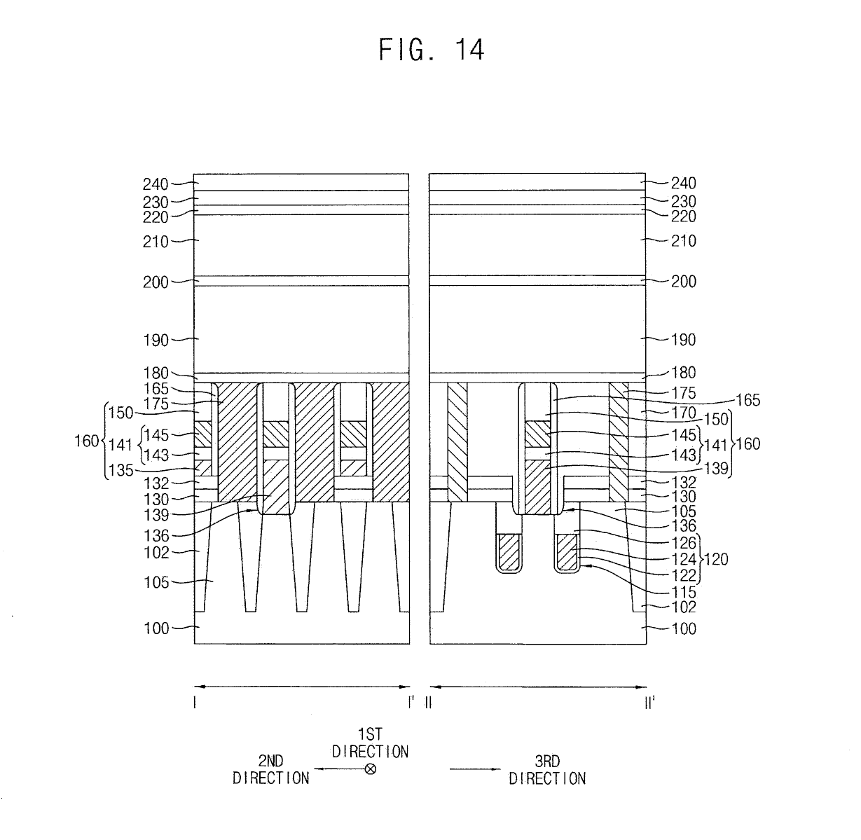

Referring to FIG. 14, a second etch stop layer 180, a first mold layer 190, a first support layer 200, a second mold layer 210, a second support layer 220, a third mold layer 230 and a third support layer 240 may be sequentially formed on the insulating interlayer 170, the contact plug 175 and the second hard mask 150.

The second etch stop layer 180 may be formed of, for example, a nitride, for example, silicon nitride, silicon oxynitride, or the like, the first to third mold layers 190, 210 and 230 may be formed of, for example, silicon oxide, for example, BSG, BPSG, TEOS, USG or the like. In some example embodiments, the third mold layer 230 may be formed of, for example, silicon nitride. The etch stop layer 150 and the mold layers 190, 210 and 230 may be formed by, for example, a CVD process, a PVD process, or the like.

The first to third support layers 200, 220 and 240 may be formed of, for example, silicon nitride, silicon carbonitride, or the like, by, for example, a CVD process, a PVD process, or the like.

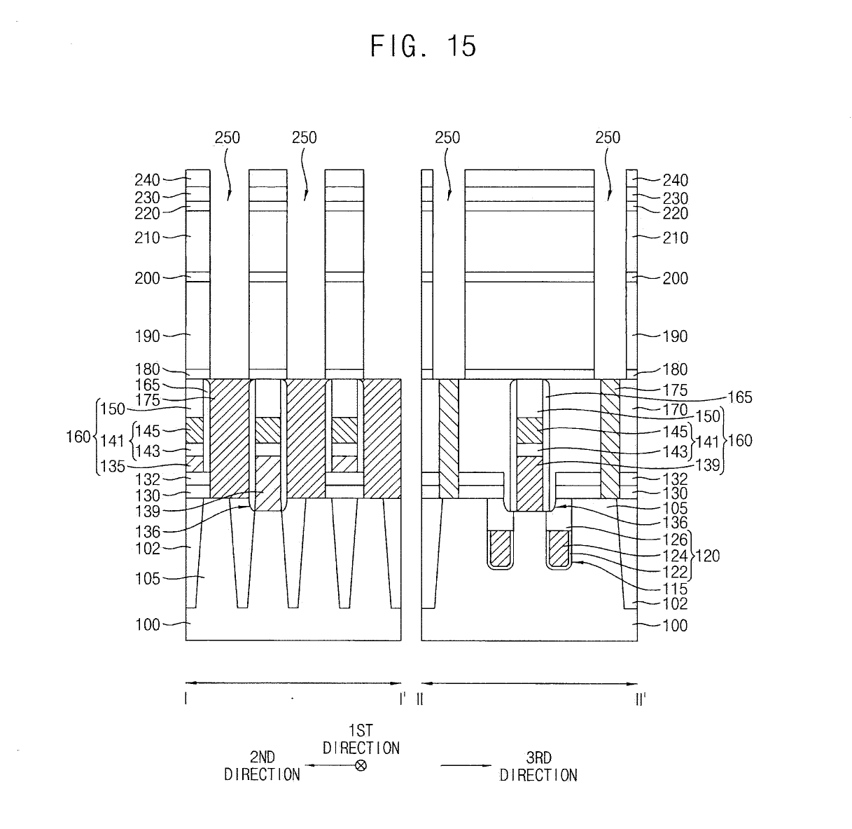

Referring to FIG. 15, the third support layer 240, the third mold layer 230, the second support layer 220, the second mold layer 210, the first support layer 200, the first mold layer 190 and the second etch stop layer 180 may be partially removed to form first openings 250 each of which may expose an upper surface of the contact plug 175. The first openings 250 may also expose a portion of the insulating interlayer 170. The first openings may extend in a substantially vertical direction of extension relative to a substantially horizontal direction of extension of the substrate 100.

The first openings 250 may be formed by, for example, a dry etching process. Due to the characteristics of the dry etching process, an upper portion of the first opening 250 may be wider than a lower portion thereof. Even in this embodiment, the third mold layer 230 may be formed of silicon oxynitride unlike the underlying first and second mold layers 190 and 210, and, as a result, the upper portion of the first opening 250 may be formed not to be too wide relative to a lower portion thereof.

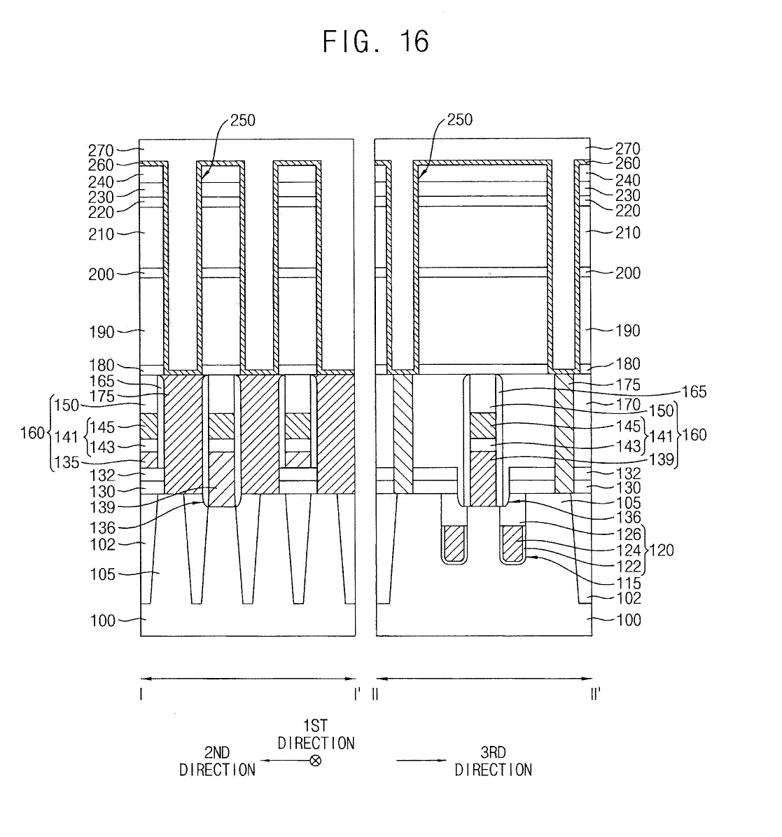

Referring to FIG. 16, a lower electrode layer 260 may be formed on the exposed upper surface of the contact plug 175, on a sidewall of the first opening 250 and on the third support layer 240. A sacrificial layer 270 may be formed on the lower electrode layer 260 to fill a remaining portion of the first opening 250 and on the third support layer 240.

The lower electrode layer 260 may be formed of, for example, a metal, for example, titanium, tungsten, tantalum, ruthenium, or the like, or a metal nitride, for example, titanium nitride, tungsten nitride, tantalum nitride, or the like, by, for example, an ALD process or a CVD process.

The sacrificial layer 270 may be formed of, for example, silicon oxide, for example, BSG, BPSG, TEOS, USG, or the like.

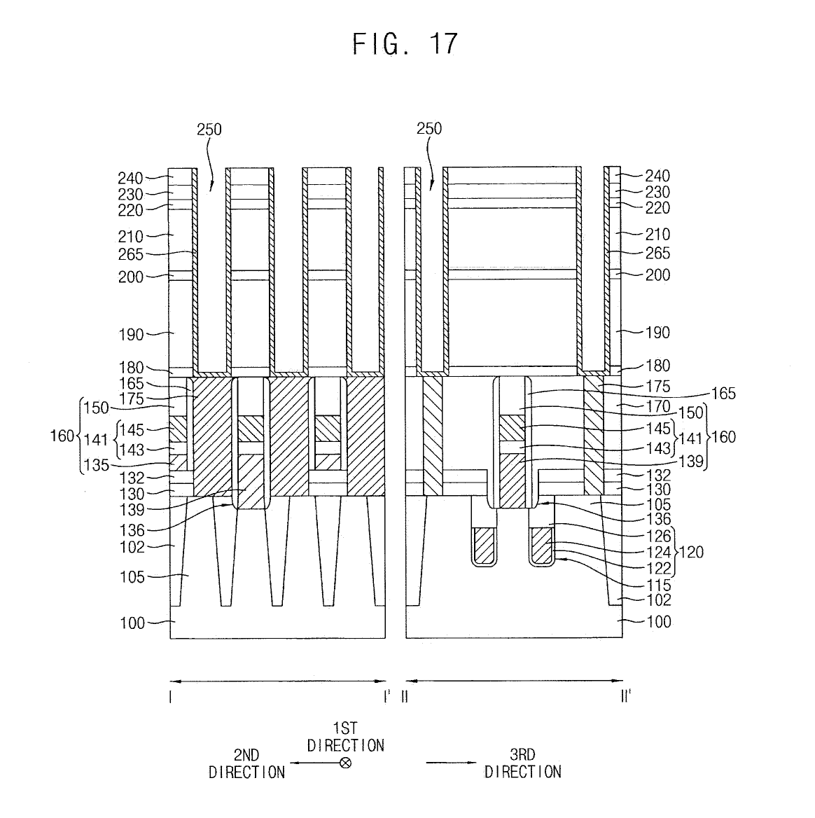

Referring to FIG. 17, the sacrificial layer 270 and the lower electrode layer 260 may be planarized until a top surface of the third support layer 240 may be exposed to form lower electrodes 265. In some example embodiments, the planarization process may be performed by, for example, a CMP process and/or an etch back process.

The remaining sacrificial layer 270 not removed during the formation of the lower electrode 265 may be removed. For example, a wet etching process may be performed using LAL to remove the sacrificial layer 270. As a result, an upper surface of the lower electrode 265 in the opening 250 may be exposed.

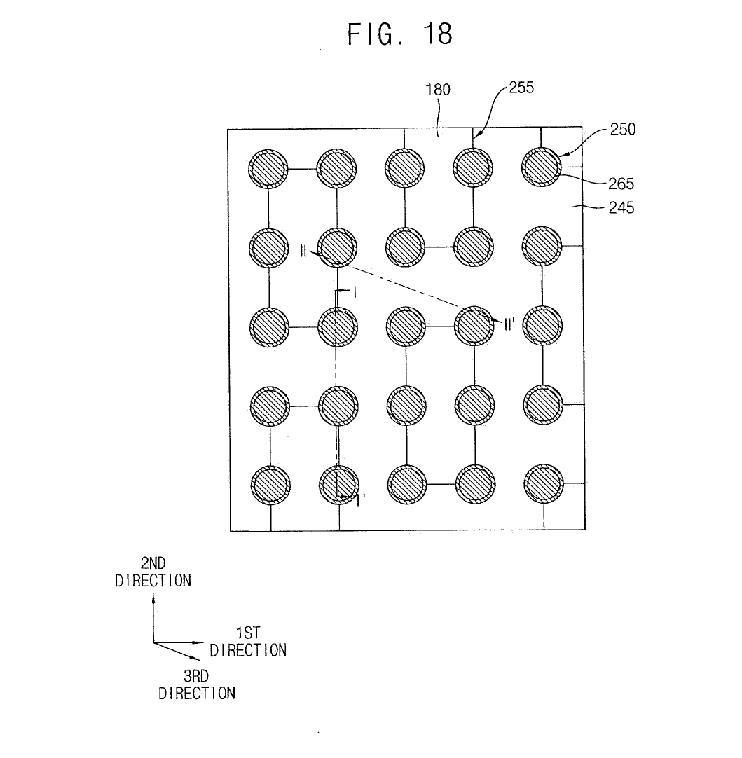

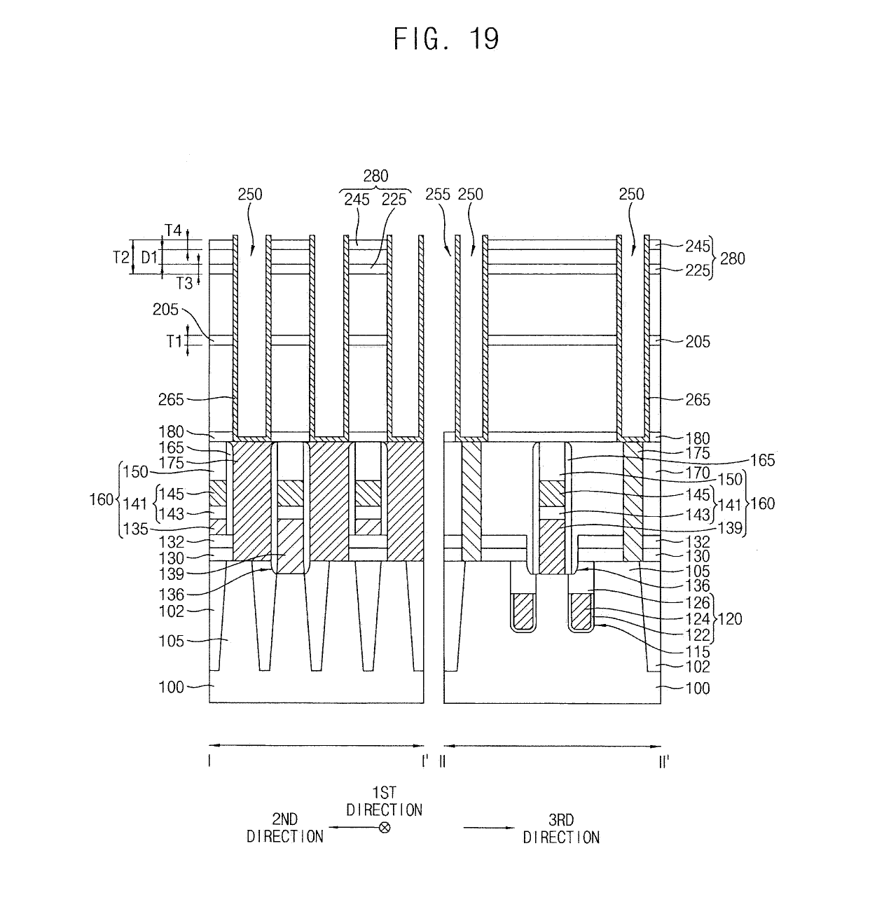

Referring to FIGS. 18 and 19, portions of the first, second and third support layers 200, 220 and 240, and the first, second and third mold layers 190, 210 and 230 may be removed.

A third hard mask (not shown) may be forming on the third support layer 240. The third hard mask may be formed by a process substantially the same as the process for forming the first hard mask 110, and may include a material substantially the same as that of the first hard mask 110.

The third support layer 240 may be partially etched by, for example, an etch back process using the third hard mask as an etching mask to form a third support pattern 245, and a second opening 255 may be formed to expose an upper surface of the third mold layer 230. FIG. 18 shows that the second opening 255 has a rectangular shape as a whole, which may be formed by neighboring six lower electrodes 265 in a plan view; however, the inventive concepts may not be limited thereto. That is, the second opening 255 may have various other shapes and/or sizes. The second opening may extend in a substantially vertical direction of extension relative to a substantially horizontal direction of extension of the substrate 100. A plurality of second openings 255 may be formed spaced apart from each other along the first direction and the second direction. After forming the second opening 255, the third hard mask may be removed.

The third mold layer 230 may be removed through the second opening 255. For example, the third mold layer 230 may be removed by, for example, a wet etching process using an etchant having an etching selectivity with respect to the second support layer 220 and the third support pattern 245. As a result, a portion of an upper surface of the second support layer 220 may be exposed.

The portion of the upper surface of the second support layer 220 exposed by the second opening 255 may be removed to form a second support pattern 225. The second support layer 220 may be removed by, for example, an etch back process. As a result, an upper surface of the second mold layer 210 may be removed.

The second mold layer 210 may be removed through the second opening 255. For example, the second mold layer 210 may be removed by, for example, a wet etching process using an etchant having an etching selectivity with respect to the first support layer 200 and the second support pattern 225. As a result, a portion of an upper surface of the first support layer 200 may be exposed.

The portion of the upper surface of the first support layer 200 exposed by the second opening 255 may be removed to form a first support pattern 205. The first support layer 200 may be removed by, for example, an etch back process. As a result, an upper surface of the first mold layer 190 may be removed.

The first mold layer 190 may be removed through the second opening 255. For example, the first mold layer 190 may be removed by, for example, a wet etching process using an etchant having an etching selectivity with respect to the first support pattern 205 and the second etch stop layer 180. As a result, a portion of an upper surface of the second etch stop layer 180 may be exposed.

By the above etching processes, the first to third mold layers 190, 210 and 230 may be removed, and the first to third support layers 200, 220 and 240 may be partially removed only at portions thereof overlapping with the second opening 255. By the above etching process, the second etch stop layer 180 may be exposed in the second opening 255.

In some example embodiments, when the first to third support patterns 205, 225 and 245 are formed, an upper surface of the third support pattern 245 may be also removed. As a result, an upper surface of the third support pattern 245 may be lower than a top surface of the lower electrode 265.

As the third mold layer 230 is removed, an upper support pattern structure 280 including the second support pattern 225 and the third support pattern 245 may be formed. The upper support pattern structure 280 and the lower support pattern including first support pattern 205 may form a support pattern structure. The upper support pattern 280 and lower support pattern including the first support pattern 205 may prevent the lower electrode 265 from falling down or being bent by the support pattern structure.

The first support pattern 205 of the lower support pattern may be formed to have a first thickness T1, and the upper support pattern structure 280 may be formed to have a second thickness T2. The second thickness T2 may be a total thickness of a sum of thicknesses of elements of the upper support pattern structure 280 and a distance therebetween. In some example embodiments, the first thickness T1 may be smaller than the second thickness T2.

In the upper support pattern structure 280, the second support pattern 225 may be formed to have a third thickness T3, the third support pattern 245 may be formed to have a fourth thickness T4, and the second and third support patterns 225 and 245 may be spaced apart from each other by a first distance D1. A sum of the third and fourth thicknesses T3 and T4 and the first distance D1 may be equal to the total thickness of the upper support pattern structure 280, that is, the second thickness T2.

In some example embodiments, a sum of the thickness of the second support pattern 225 and the thickness of the third support pattern 245, that is, T3+T4, may be about 35% to about 85% of the total thickness of the upper support pattern structure 280, that is, the second thickness T2. The first distance D1 between the second support pattern 225 and the third support pattern 245 may be about 15% to about 65% of the second thickness T2 of the upper support pattern structure 280. If the first distance D1 is less than about 15% of the second thickness T2 of the upper support pattern structure 280, the dielectric layer 290 may not be formed between the second support pattern 225 and the third support pattern 245. If the first distance D1 is more than about 65% of the second thickness T2 of the upper support pattern structure 280, the lower electrode 265 may not be sufficiently supported. Thus, the first distance D1 may be between 15% and 65% of the second thickness T2.

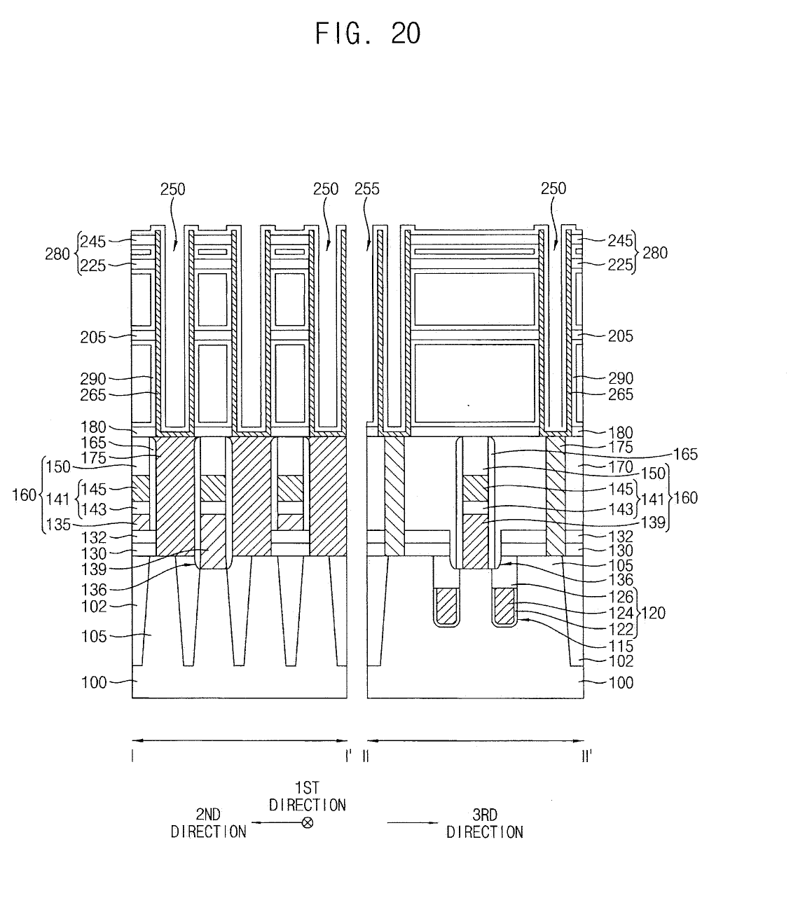

Referring to FIG. 20, a dielectric layer 290 may be conformally formed on the lower electrode 265, the second etch stop layer 180, and the first, second and third support patterns 205, 225 and 245. The dielectric layer 290 may be formed in the first opening 250 and the second opening 255 and between first, second and third support patterns 205, 225 and 245, respectively.

The dielectric layer 290 may be formed of, for example, a metal oxide having a high dielectric constant, for example, hafnium oxide, zirconium oxide, or the like, by, for example, a CVD process, an ALD process, or the like.

Referring to FIGS. 1 and 2, an upper electrode 295 may be formed on the dielectric layer 290 to form a capacitor 300.

The upper electrode 295 may be formed of, for example, a metal, for example, titanium, tungsten, tantalum, ruthenium, or the like, or a metal nitride, for example, titanium nitride, tungsten nitride, tantalum nitride, or the like, by, for example, a CVD process, an ALD process, a PVD process, or the like.

The lower support pattern 205 may be separated from the upper support pattern structure 280 in a direction substantially perpendicular to the upper surface of the substrate 100. That is, the lower support pattern 205 may be separated from the upper support pattern structure 280 in a substantially vertical direction of extension relative to a substantially horizontal direction of extension of the substrate 100. The second support pattern 225 and the third support pattern 245 of the upper support pattern structure may be separated in a direction substantially perpendicular to the upper surface of the substrate 100. The lower support pattern 205 may be separated from the upper support pattern structure 280 by a greater distance than the second support pattern 225 is separated from the third support pattern 245.

Each of the lower support pattern 205 and the upper support pattern structure 280 may extend in a direction substantially parallel to the top surface of the substrate between sidewalls of the lower electrodes 265. Each of the lower support pattern 205 and the upper support pattern structure 280 may partially connect the sidewalls of the lower electrodes 265 to each other.

The foregoing is illustrative of some example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A capacitor structure, comprising:
a plurality of lower electrodes on a substrate;
a support pattern structure between the lower electrodes, the support pattern structure including:
a lower support pattern; and
an upper support pattern structure over the lower support pattern, the upper support pattern structure including a plurality of upper support patterns spaced apart from each other in a direction substantially perpendicular to a top surface of the substrate;
a dielectric layer on the lower electrodes and the support pattern structure; and
an upper electrode on the dielectric layer,
wherein a sum of thicknesses of the plurality of upper support patterns in the direction substantially perpendicular to the top surface of the substrate is about 35% to about 85% of a total thickness of the upper support pattern structure.

2. The capacitor structure of claim 1, wherein a thickness of the lower support pattern is smaller than the total thickness of the upper support pattern structure.

3. The capacitor structure of claim 1, wherein the lower support pattern includes a first support pattern,
and wherein the upper support pattern structure includes second and third support patterns spaced apart from each other in the direction substantially perpendicular to the top surface of the substrate, and a distance between the second and third support patterns in the direction substantially perpendicular to the top surface of the substrate is about 15% to about 65% of the total thickness of the upper support pattern structure.

4. The capacitor structure of claim 1, wherein an upper surface of the upper support pattern structure is lower than top surfaces of the lower electrodes.

5. The capacitor structure of claim 1, wherein the lower support pattern and the upper support pattern structure include silicon nitride or silicon carbonitride.

6. The capacitor structure of claim 1, wherein each of the lower support pattern and the upper support pattern structure extends in a direction substantially parallel to the top surface of the substrate between sidewalls of the lower electrodes.

7. The capacitor structure of claim 6, wherein each of the lower support pattern and the upper support pattern structure partially connects the sidewalls of the lower electrodes to each other.

8. The capacitor structure of claim 7, wherein the upper support pattern structure vertically overlaps the lower support pattern.

9. The capacitor structure of claim 1, wherein the lower electrode has a cylindrical shape.

10. A semiconductor device, comprising:
a transistor on a substrate; and
a capacitor structure electrically connected to the transistor, the capacitor including:
a plurality of lower electrodes on the substrate;
a support pattern structure between the lower electrodes, the support pattern structure including:
a lower support pattern; and
an upper support pattern structure over the lower support pattern, the upper support pattern structure including a plurality of upper support patterns spaced apart from each other in a direction substantially perpendicular to a top surface of the substrate;
a dielectric layer on the lower electrodes and the support pattern structure; and
an upper electrode on the dielectric layer,
wherein a sum of thicknesses of the plurality of upper support patterns in the direction substantially perpendicular to the top surface of the substrate is about 35% to about 85% of a total thickness of the upper support pattern structure.

11. The semiconductor device of claim 10, wherein the lower support pattern includes a first support pattern,
and wherein the upper support pattern structure includes second and third support patterns spaced apart from each other in the direction substantially perpendicular to the top surface of the substrate, and a distance between the second and third support patterns in the direction substantially perpendicular to the top surface of the substrate is about 15% to about 65% of the total thickness of the upper support pattern structure.

12. The semiconductor device of claim 10, wherein an upper surface of the upper support pattern structure is lower than top surfaces of the lower electrodes.

13. The semiconductor device of claim 10, wherein each of the lower support pattern and the upper support pattern structure extends in a direction substantially parallel to the top surface of the substrate between sidewalls of the lower electrodes,
and wherein the upper support pattern structure vertically overlaps the lower support pattern.

14. The semiconductor device of claim 10, wherein the transistor includes a gate structure buried in the substrate.

15. The semiconductor device of claim 10, further comprising a contact plug electrically connected to the transistor, the contact plug contacting the capacitor structure.

16. A capacitor structure, comprising:
a plurality of lower electrodes on a substrate;
a lower support pattern between the lower electrodes and spaced apart from the substrate in a first direction, the first direction being substantially perpendicular to a direction of extension of an upper surface of the substrate;
an upper support pattern structure comprising a plurality of upper support patterns between the plurality of lower electrodes and spaced apart from the lower support pattern in the first direction, the plurality of upper support patterns being spaced apart from each other in the first direction;
a dielectric layer on the lower electrodes, the lower support pattern and the plurality of upper support patterns; and
an upper electrode on the dielectric layer,
wherein a sum of distances between the plurality of upper support patterns in the first direction is about 15% to about 65% of a total thickness of the upper support pattern structure.

17. The capacitor structure of claim 16, wherein the lower support pattern includes a first support pattern,
and wherein the plurality of upper support patterns include second and third support patterns spaced apart from each other in the first direction, a distance between the second and third support patterns in the first direction is about 15% to about 65% of the total thickness of the upper support pattern structure, and a sum of thicknesses of the plurality of upper support patterns in the first direction is about 35% to about 85% of a total thickness of the upper support pattern structure.

18. The capacitor structure of claim 16, wherein an upper surface of the upper support pattern structure is lower than top surfaces of the lower electrodes.

19. The capacitor structure of claim 16, wherein each of the lower support pattern and the upper support pattern structure extends in a direction substantially parallel to the top surface of the substrate between sidewalls of the lower electrodes, and
wherein each of the lower support pattern and the upper support pattern structure partially connects the sidewalls of the lower electrodes to each other.

20. The capacitor structure of claim 19, wherein the upper support pattern structure vertically overlaps the lower support pattern.
